(19) United States
(12) Patent Application Publication
(10) Pub. No.: US 2023/0375822 A1
(43) Pub. Date: Nov. 23, 2023

(54) FLIP CHIP MICROMIRROR TECHNOLOGY

(71) Applicant: Microsoft Technology Licensing, LLC, Redmond, WA (US)

(72) Inventors: Xiao Chuan ONG, Bellevue, WA (US); Di SUN, Bothell, WA (US); Joseph Michael LUIZZI, Sammamish, WA (US); Wyatt Owen DAVIS, Bothell, WA (US)

(21) Appl. No.: 17/750,009

(22) Filed: May 20, 2022

(51) Int. Cl. G02B 26/08; B81B 7/00; G02B 26/10

(52) U.S. Cl. CPC G02B 26/0833; B81B 7/007; G02B 26/101; B81B 2201/042; B81B 2203/058; B81B 2203/04; B81B 2207/098

(57) ABSTRACT

A flip chip micromirror assembly comprising a micromirror chip that is flip chip mounted onto the circuit board via a bonding layer. The micromirror chip has a micromirror layer in which a micromirror is formed. The micromirror chip has a flip chip surface facing the electrode surface of the circuit board. The bonding layer includes conductive region(s) that electrically couples corresponding board electrodes with corresponding chip electrodes. However, the bonding layer is not interposed between the electrode surface of the circuit board and the micromirror itself. In other words, the bonding layer spaces the micromirror chip from the circuit board, and provides a gap underneath the micromirror between the micromirror chip and the circuit board. This gap is of sufficient thickness that the micromirror can be actuated with full movement without being mechanically obstructed by the circuit board.

### BACKGROUND

A Micro-ElectroMechanical System (or MEMS) device is a miniature machine that has both mechanical and electrical components. The physical dimension of a MEMS device can range from on the order of millimeters to less than one micrometer, a dimension many times smaller than the width of a human hair. One type of device that has been implemented as a MEMS device is a micromirror.

Micromirrors are devices used in optical systems to direct light from one position to another over a range of reflection angles. The reflection angle of a micromirror can be adjusted by an actuation mechanism that rotates and moves the mirror surface. Thus, the mirror surface should be capable of rotating. Actuation mechanisms for MEMS micromirrors include electrostatic, piezoelectric, electromagnetic and electrothermal actuation mechanisms.

MEMS micromirrors are very small and light. Accordingly, they have conventionally been used in wearable eye devices, such as a headset, where an image is projected into a field of view. Such might be performed to enable augmented, virtual, and mixed reality user experiences. The light source may be a laser where horizontal scanning is accomplished by control of one high frequency MEMS micromirror, and vertical scanning is accomplished by control of a lower frequency MEMS micromirror. Electrical signals are provided to each MEMS micromirror to direct the laser light appropriately to perform the scanning.

The subject matter claimed herein is not limited to embodiments that solve any disadvantages or that operate only in environments such as those described above. Rather, this background is only provided to illustrate one exemplary technology area where some embodiments describe herein may be practiced.

### BRIEF SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

The principles described herein relate to a flip chip micromirror assembly comprising a circuit board and a micromirror chip that is bonded in flip chip configuration onto the circuit board via a bonding layer. The flip chip configuration allows for stronger structural integrity of the bonds between the circuit board and the micromirror chip, and allows for a more compact and light-weight package. Furthermore, notwithstanding the flip chip configuration, the micromirror is still fully actuatable.

The circuit board has an electrode surface in which one or more board electrodes are formed. The micromirror chip has a micromirror structural layer in which a micromirror is formed. The micromirror chip has a flip chip surface facing the electrode surface of the circuit board, and has one or more chip electrodes formed therein. A bonding layer is interposed between the electrode surface of the circuit board and the flip chip surface of the micromirror layer. The bonding layer includes one or more conductive region that electrically couples corresponding one or more board electrodes of the circuit board with corresponding one or more chip electrodes of the micromirror layer.

However, the bonding layer is not interposed between the electrode surface of the circuit board and the micromirror itself. In other words, the bonding layer provides a gap underneath the micromirror between the micromirror chip and the circuit board. This gap is of sufficient thickness that the micromirror can be actuated with full movement without being mechanically obstructed by the circuit board.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and details through the use of the accompanying drawings in which:

FIG. 1 illustrates a general side view of a micromirror chip, in which a micromirror structural layer is formulated on a substrate, according to one embodiment described herein;

FIG. 2 illustrates a detailed plan view of the micromirror chip, which illustrates more details of the layers forming the micromirror structural layer, in accordance with one example described herein;

FIG. 3 illustrates a flowchart of a method for manufacturing a flip chip micromirror assembly, in accordance with the principles described herein;

FIG. 4 illustrates a plan view of a flip chip micromirror assembly that is produced by performing the method of FIG. 3 with respect to the micromirror chip of FIGS. 1 and 2;

FIG. 5 illustrates a plan view of a circuit board with an electrode surface facing upward, and showing board electrodes that would align with the corresponding chip electrodes after the micromirror chip is flipped;

FIG. 6 illustrates an uncompressed anisotropic film prior to compression and a compressed anisotropic film after compression;

FIG. 7 illustrates a bottom view of a micromirror assembly, in which there is a hole formed through the circuit board through which incident and reflected light may pass;

FIG. 8 illustrates an optical system in the form of a head-mounted device (or HMD) that has a display, in which one or more micromirror assemblies may be positioned as part of an optical system that projects onto the display; and

FIG. 9 illustrates a computing system that may be used to implement an actuator component that actuates one or more micromirrors of an optical system.

### DETAILED DESCRIPTION

The principles described herein relate to a flip chip micromirror assembly comprising a circuit board and a micromirror chip that is bonded in flip chip configuration onto the circuit board via a bonding layer. The flip chip configuration allows for stronger structural integrity of the bonds between the circuit board and the micromirror chip, and allows for a more compact and light-weight package. Furthermore, notwithstanding the flip chip configuration, the micromirror is still fully actuatable.

The circuit board has an electrode surface in which one or more board electrodes are formed. The micromirror chip has a micromirror structural layer in which a micromirror is formed. The micromirror chip has a flip chip surface facing the electrode surface of the circuit board, and has one or more chip electrodes formed therein. A bonding layer is interposed between the electrode surface of the circuit board and the flip chip surface of the micromirror layer. The bonding layer includes one or more conductive region that electrically couples corresponding one or more board electrodes of the circuit board with corresponding one or more chip electrodes of the micromirror layer.

However, the bonding layer is not interposed between the electrode surface of the circuit board and the micromirror itself. In other words, the bonding layer provides a gap underneath the micromirror between the micromirror chip and the circuit board. This gap is of sufficient thickness that the micromirror can be actuated with full movement without being mechanically obstructed by the circuit board.

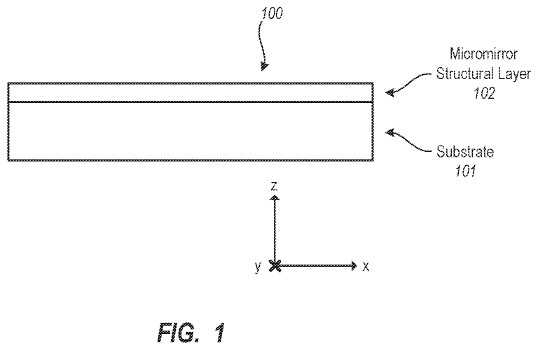

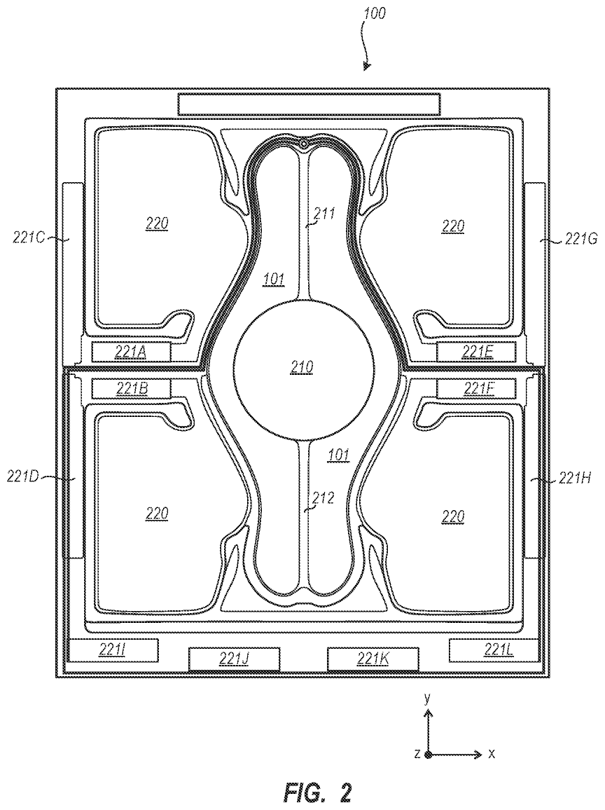

First, the structure of an example micromirror chip will be described. FIG. 1 illustrates a general side view of the micromirror chip 100, and FIG. 2 illustrates a detailed plan view of the micromirror chip 100. The principles described herein are not limited to the micromirror chip 100 of FIGS. 1 and 2, but may be used with any micromirror chip that includes an actuatable micromirror. Accordingly, the micromirror chip 100 should be viewed as a mere example of an innumerable variety of micromirror chips that the principles described herein may use as a flip chip.

In the particular example, micromirror chip 100 of FIG. 1, the micromirror chip is rectangular in plan view, but with a thickness. Such might be the case if, for example, multiple instances of the micromirror chip 100 were fabricated using semiconductor manufacturing techniques on a semiconductor wafer, and then each micromirror chip 100 was thereafter cut into a rectangular die shape.

A three-dimensional coordinate system is also illustrated throughout the figures for more convenient reference, where the x-axis, y-axis and z-axis are each orthogonal to each other. The x-axis is parallel to the shorter rectangular side of the micromirror chip 100 in plan view. The y-axis is parallel to the longer rectangular side of the micromirror chip 100. The z-axis is in the thickness direction of the micromirror chip 100. In FIG. 1, the x-axis is horizontal with the positive x-direction going rightward, the z-axis is vertical with the positive z-direction going upwards, and the y-axis is perpendicular to the plane of the diagram with the positive y-direction going away from the reader. In FIG. 2, the x-axis is horizontal with the positive x-direction going rightward, the y-axis is vertical with the positive y-direction going upwards, and the z-axis goes is perpendicular to the plane of the diagram with the positive z-direction going towards the reader.

As best seen in FIG. 1, the micromirror chip 100 comprises a micromirror structural layer 102 formed on a substrate 101. As an example, the substrate 101 could be a diced portion of a silicon wafer. The micromirror structural layer 102 may include multiple layers of different compositions and structures. However, such layers are simply represented as a micromirror structural layer 102 in FIG. 1. A micromirror is formed within the micromirror structural layer 102 such that with applied actuation, the micromirror can be tilted, thereby controlling a reflection angle of light incident on that micromirror.

FIG. 2 illustrates a plan view of the micromirror chip 200 looking down on the micromirror layer (i.e., looking in the negative z-direction). Here, the micromirror 210 (which is generally circular) is shown as connected to the rest of the micromirror chip 100 only with tortional bars 211 and 212. Furthermore, there is space underneath (in the negative z-direction) the micromirror 210. Thus, the micromirror 210 is free to tilt about a tilting axis (parallel to the y-axis) along which the tortional bars 211 and 212 are elongated with the micromirror not coming into mechanical contact with other parts of the micromirror chip 100. Thus, the micromirror 210 is tiltable about the tilting axis in response to actuation, while the tortional bars 211 and 212 elastically urge restoring the micromirror 210 to its original position parallel to the xy plane. In one embodiment, the space underneath the micromirror 210 extends all the way down to the substrate 101. Thus, in FIG. 2, the substrate 101 may be visible.

The micromirror assembly also induces an electrode layer 220 in which chip electrodes are placed. In the illustrated embodiment of FIG. 2, the electrode layer 220 includes twelve electrodes 221A through 221L, which may each be referred to herein as “chip electrodes” since they are formed in the micromirror chip 100 to distinguish them from electrodes formed in a circuit board that will be described hereinafter. The chip electrodes 221A through 221L may also be referred to collectively a “chip electrodes 221” or individually as “each chip electrode 221”. Each chip electrode 221 is electrically connected to an appropriate electrical element below the electrode layer 220. As an example, there may be chip electrodes to provide a power supply, to measure strain from a strain sensor, to provide actuation signals, and so forth. The electrode layer 220 is an example of a “flip chip surface” in which one or more chip electrodes are formed.

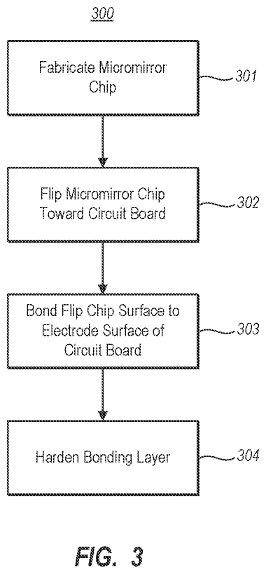

FIG. 3 illustrates a flowchart of a method 300 for manufacturing a flip chip micromirror assembly, in accordance with the principles described herein. The method 300 includes fabricating a micromirror chip having a micromirror structural layer in which a micromirror is formed, and including a flip chip surface having at least one chip electrode formed therein (act 301). The manufacture of the micromirror assembly 100 of FIGS. 1 and 2 is an example of this act 301.

After the micromirror chip is fabricated (act 301), the fabricated micromirror chip is flipped towards an electrode surface of a circuit board, so that the flip chip surface of the micromirror chip faces the electrode surface of the circuit board (act 302). Thus, the micromirror is flipped upside down so that the micromirror structural layer 102 faces downwards in the minus z-direction, rather than as shown facing upwards in the positive z-direction as in FIG. 1.

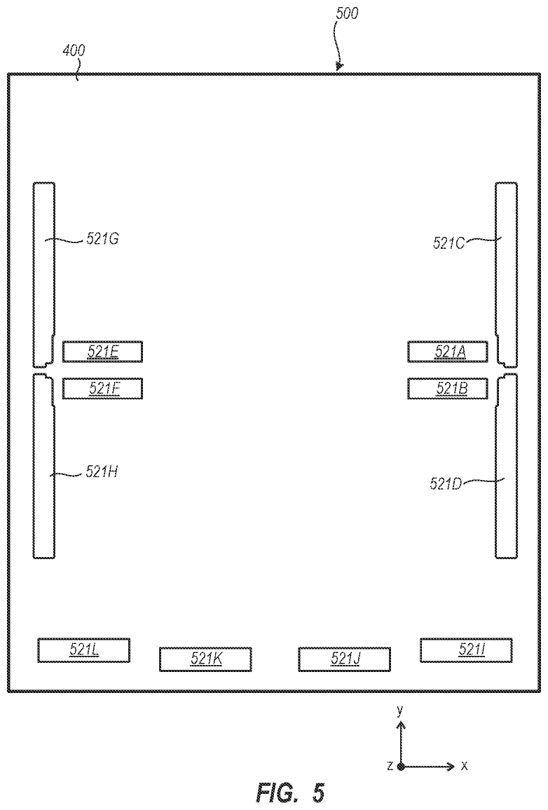

The flip chip surface of the micromirror chip is then bonded to the electrode surface of the circuit board with a bonding layering interposed between the flip chip surface of the micromirror chip and the electrode surface of the circuit board (act 303). This bonding occurs such that that the bonding layer has conductive regions that each electrically coupled through the bonding material one or more of the chip electrodes with one or more board electrodes of the circuit board. As an example, FIG. 5 illustrates a plan view of a circuit board 500 with an electrode surface facing upward (in the positive z-direction), and showing board electrodes 521A through 521L that would align with the corresponding chip electrodes 221A through 221L after the micromirror chip 100 is flipped.

The bonding layer is then hardened (act 304) with compressive force downward (in the minus z direction) so that the bonding layer structurally supports the flipped micromirror chip on the circuit board while providing a space for the micromirror to be fully actuated. As an example, the micromirror assembly may be heated to thermally cure the bonding layer, so that the micromirror chip is fixed with respect to the circuit board.

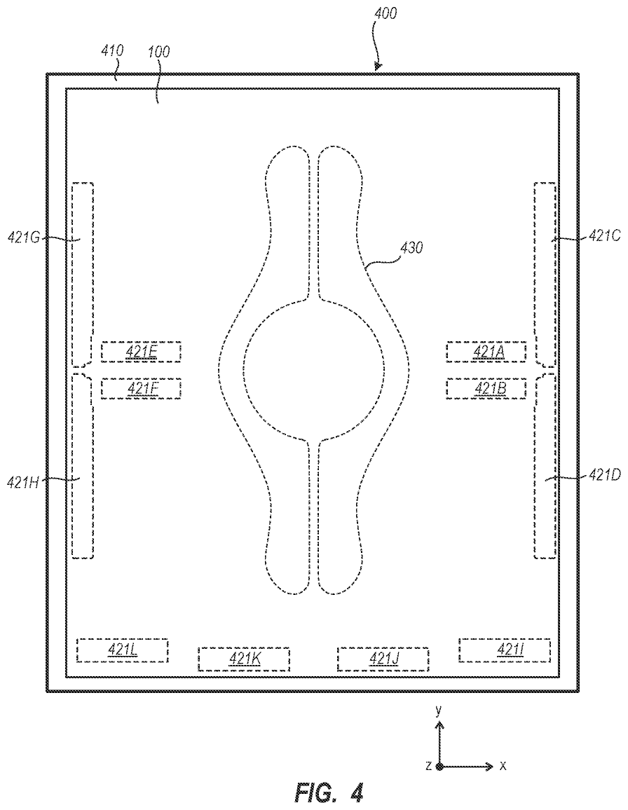

FIG. 4 illustrates a plan view of a flip chip micromirror assembly 400 that is produced by performing the method 300 with respect to the micromirror chip 100 of FIGS. 1 and 2. In FIG. 4, the x-axis is horizontal with the positive x-direction going rightward, the y-axis is vertical with the positive y-direction going upwards, and the z-axis is perpendicular to the plane of the diagram with the positive z-direction going towards the reader.

In FIG. 4, a circuit board 410 is shown underneath (in the negative z-direction) the micromirror chip 100. The micromirror chip 100 is shown flipped over so that the chip electrode surface of the micromirror layer is now facing downward (in the negative z-direction) towards the board electrode surface of the circuit board 410 which is facing upwards (in the positive z-direction). This would visually obscure the electrode connections between the chip electrodes and the board electrodes, which is what makes this a flip chip configuration. However, to illustrate the principles herein, conductive regions 421A through 421L of the bonding layer are shown in dashed-lined form. In addition, with the substrate of the chip assembly still in place, the micromirror and associated cavity in which the micromirror can move would also not be visible, though for clarity the outline of the micromirror, the tortional bars and associated micromirror cavity are illustrated as a dotted line.

Each of the conductive regions 421A through 421L would align in plan view with a corresponding chip electrode 221A through 221L, and a corresponding board electrode 521A through 521L. For instance, conductive region 421A would align with chip electrode 221A, which would now be towards the right since the micromirror chip is flipped, and serve to electrically connect the chip electrode 221A and the board electrode 521A. Likewise, each of conductive regions 421B through 421L would align in plan view with corresponding chip electrodes 221B through 221L, and serve to connect their respective chip electrode 221B through 221L to the respective board electrode 521B through 521L.

While there may be a one-to-one connection between board electrodes and chip electrodes for each conductive region, that need not be the case. As a simple example, there may be multiple voltage supply board electrodes that map to a single voltage supply chip electrode and/or multiple voltage supply chip electrodes that map to a single voltage supply board electrode.

Due to the flip chip configuration, the micromirror assembly 400 may be made much smaller in plan view since no plan layout is required for bonding wires, and because the chip electrodes and respective board electrodes may occupy the same plan space. Furthermore, the flip chip configuration allows the micromirror assembly 400 to have less thickness as there are no bond wires extending upwards from the micromirror assembly, nor is there required to be any protective encasing for protecting fragile bond wires. Instead, the electrical connections are safely protected within the micromirror assembly itself.

The bonding layer is positioned between the electrode surface of the circuit board and the electrode surface of the micromirror chip at the regions (in plan) view corresponding to the electrodes. Thus, the bonding layer provides appropriate electrical connection between the circuit board and the micromirror chip. However, the bonding layer is not positioned between the electrode surface of the circuit board and the micromirror itself in the micromirror chip. Accordingly, after hardening, the bonding layer spaces the circuit board from the micromirror. This allows the micromirror to tilt about the tilting axis without contacting the underlying circuit board, notwithstanding that the micromirror chip is flip chip bonded to the circuit board.

Accordingly, the spacing between the circuit board and the micromirror layer should be carefully controlled so as not to be so small that the micromirror makes mechanical contact with the circuit board thereby disrupting the micromirror performance, while not being so large that the flip chip micromirror assembly is too thick. In one example, this is does by using an anisotropic conductive film (sometimes called ASF). Anisotropic conductive film contains small spheres that when compressed allows electrical conductivity in the direction of compression.

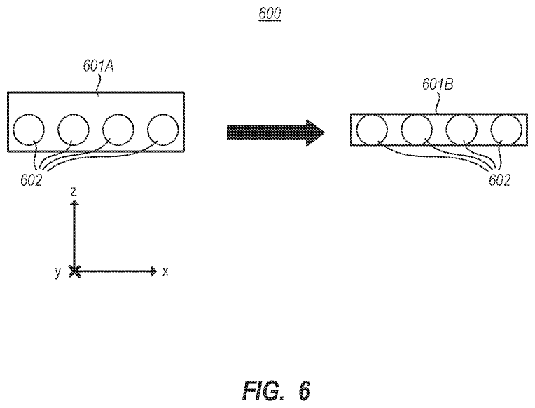

FIG. 6 illustrates an uncompressed anisotropic film 601A prior to compression and a compressed anisotropic film 601B after compression. Compression of the film is easily performed until the thickness of the film is reduced to the diameter of the spheres 602. Then, compression can be performed a little more to slightly deform the spheres 602 and put the spheres under compression, thereby activating their conductive property in the z-directions. By designing the spheres to be larger than the gap needed between the circuit board and micromirror chip, the appropriate spacing to allow for micromirror actuation may be secured. As an example, if the micromirror is displaced by a maximum distance Q in the z-direction, the anisotropic conductive film with spheres of diameter (1+S)Q may be used, where S is a safety factor. As an example, the safety factor S could be 40 percent. The safety factor should be sufficient to allow for some compression of the conductive spheres, and some anticipated occasional accelerations (e.g., shock) anticipated to be potentially experienced by the flip chip micromirror assembly. The distance between the flip chip surface of the micromirror structural layers and the electrode layer of the circuit board is thus controlled by the diameter of the conductive spheres in the compression direction.

The principles described herein are not limited to the use of an anisotropic conductive film as a bonding layer. As an example, the bonding layer could be formed from a bulk bonding material, which is typically less expensive up front, but would require a more careful check to make sure the proper spacing between the circuit board and micromirror has been achieved.

The micromirror has a most reflective side, which is the side on which light be caused to be directed from a light source. The tilt of the micromirror causes the reflected light to be directed with different angles depending on the tilt. This most reflective side of the micromirror will also be called herein a “reflection surface”. In one embodiment, this reflection surface is on a side of the micromirror chip that faces the circuit board. In this case, light is incident upon the reflection surface through a hole formed in the circuit board, and light is reflected from the reflection surface again through the hole in the circuit board. This has an advantage of requiring less complexity in formulating the micromirror chip, since the substrate 101 of the micromirror chip can remain in place. However, the incident angle and reflectance angle is more limited since steeper angles will be obscured by the circuit board.

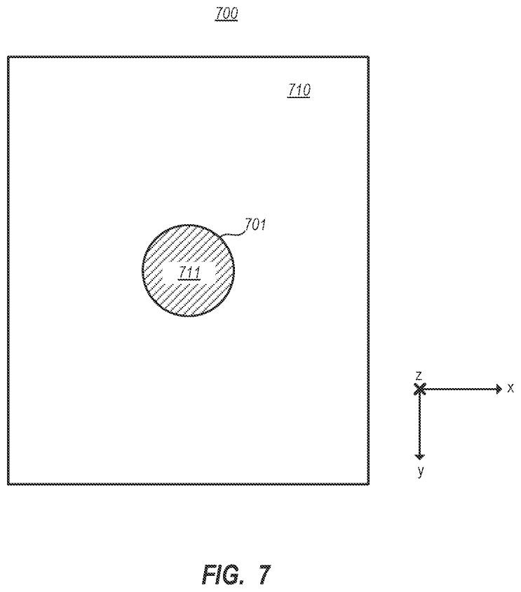

FIG. 7 illustrates a bottom view (in the positive z-direction) of a micromirror assembly 700. Here, there is a hole 701 formed in the circuit board 710, with a micromirror 711 of the micromirror chip being visible through the hole 701. Light is incident on the micromirror 711 after having passed through the hole 701, and light reflects from the micromirror 711 and thereafter again passes through the hole 701.

In another embodiment, the reflective side of the micromirror is on a side opposite the flip chip surface of the micromirror layer and facing away from the circuit board. However, as will be apparent from this description, the substrate 101 of the micromirror chip 100 is opaque and does not allow light to pass through. Accordingly, the substrate 101 of the micromirror is removed in this case. This may be achieved by forming an etch stop layer first on top of the silicon substrate as the first layer in the formation of the micromirror chip. Then, the layer comprising the micromirror itself is thereafter formed. When the micromirror chip is turned over, the substrate 101 can then be etched, with the etching stopping at the etch stop layer. A reflective layer may then be patterned on the micromirror whilst the micromirror is in the flip chip configuration. This clearly involves more complexity in manufacturing, but allows for much wider angles of incident light and reflected light.

Accordingly, the principles described herein describe a micromirror assembly that is flip chip bonded to its underlying circuit board whilst still allowing for actuation of the micromirror. Thus, the micromirror assembly can be made very small and light. Such may be particularly useful for a wearable device, such as for instance glasses or a headset that uses laser light and one or more micromirrors to direct light to scan onto a field of view to generate an augmented, virtual, or mixed reality experience.

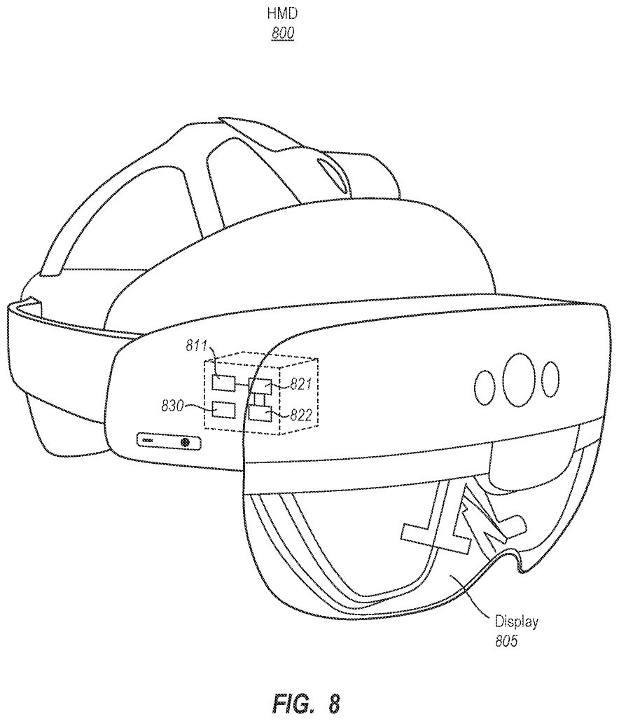

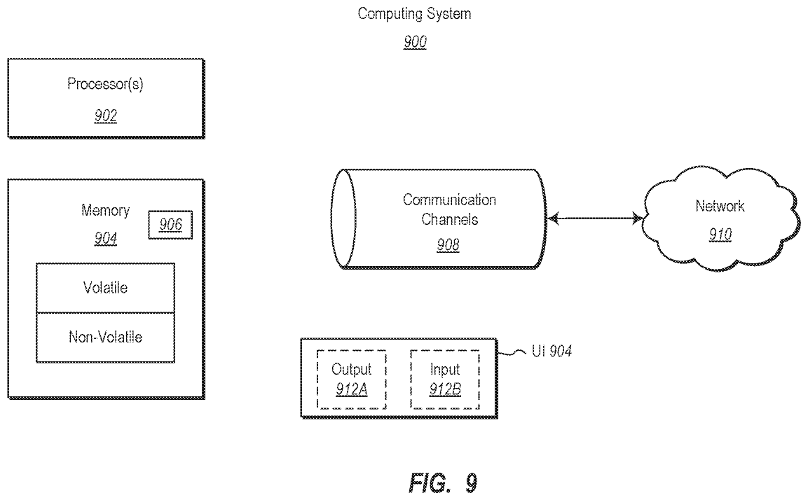

As an example, FIG. 8 illustrates an optical system 800 in the form of a head-mounted device (or HMD) that has a display. The optical system 800 includes a projection system 810 that projects images onto the display 805 of the optical system. The projection system 810 includes an optical source 811 configured to direct an optical signal incident on a reflective surface of a micromirror of a micromirror assembly 821 that is used for horizontal scanning and another micromirror assembly 822 that is used for vertical scanning. The micromirror assemblies 821 and 822 may each be structured as described above. The tilt of the micromirrors of each of the micromirror assemblies is finely controlled with an actuator controller 830, which may be structured as described below for the executable component 906 of FIG. 9.

Because the principles described herein are performed in the context of a computing system, some introductory discussion of a computing system will be described with respect to FIG. 9. Computing systems are now increasingly taking a wide variety of forms. Computing systems may, for example, be handheld devices, appliances, laptop computers, desktop computers, mainframes, distributed computing systems, data centers, or even devices that have not conventionally been considered a computing system, such as wearables (e.g., glasses). In this description and in the claims, the term “computing system” is defined broadly as including any device or system (or a combination thereof) that includes at least one physical and tangible processor, and a physical and tangible memory capable of having thereon computer-executable instructions that may be executed by a processor. The memory may take any form and may depend on the nature and form of the computing system. A computing system may be distributed over a network environment and may include multiple constituent computing systems.

As illustrated in FIG. 9, in its most basic configuration, a computing system 900 includes at least one hardware processing unit 902 and memory 904. The processing unit 902 includes a general-purpose processor. Although not required, the processing unit 902 may also include a field programmable gate array (FPGA), an application specific integrated circuit (ASIC), or any other specialized circuit. In one embodiment, the memory 904 includes a physical system memory. That physical system memory may be volatile, non-volatile, or some combination of the two. In a second embodiment, the memory is non-volatile mass storage such as physical storage media. If the computing system is distributed, the processing, memory and/or storage capability may be distributed as well.

The computing system 900 also has thereon multiple structures often referred to as an “executable component”. For instance, the memory 904 of the computing system 900 is illustrated as including executable component 906. The term “executable component” is the name for a structure that is well understood to one of ordinary skill in the art in the field of computing as being a structure that can be software, hardware, or a combination thereof. For instance, when implemented in software, one of ordinary skill in the art would understand that the structure of an executable component may include software objects, routines, methods (and so forth) that may be executed on the computing system. Such an executable component exists in the heap of a computing system, in computer-readable storage media, or a combination.

One of ordinary skill in the art will recognize that the structure of the executable component exists on a computer-readable medium such that, when interpreted by one or more processors of a computing system (e.g., by a processor thread), the computing system is caused to perform a function. Such structure may be computer readable directly by the processors (as is the case if the executable component were binary). Alternatively, the structure may be structured to be interpretable and/or compiled (whether in a single stage or in multiple stages) so as to generate such binary that is directly interpretable by the processors. Such an understanding of example structures of an executable component is well within the understanding of one of ordinary skill in the art of computing when using the term “executable component”.

The term “executable component” is also well understood by one of ordinary skill as including structures, such as hard coded or hard wired logic gates, that are implemented exclusively or near-exclusively in hardware, such as within a field programmable gate array (FPGA), an application specific integrated circuit (ASIC), or any other specialized circuit. Accordingly, the term “executable component” is a term for a structure that is well understood by those of ordinary skill in the art of computing, whether implemented in software, hardware, or a combination. In this description, the terms “component”, “agent”, “manager”, “service”, “engine”, “module”, “virtual machine” or the like may also be used. As used in this description and in the case, these terms (whether expressed with or without a modifying clause) are also intended to be synonymous with the term “executable component”, and thus also have a structure that is well understood by those of ordinary skill in the art of computing.

In the description that follows, embodiments are described with reference to acts that are performed by one or more computing systems. If such acts are implemented in software, one or more processors (of the associated computing system that performs the act) direct the operation of the computing system in response to having executed computer-executable instructions that constitute an executable component. For example, such computer-executable instructions may be embodied on one or more computer-readable media that form a computer program product. An example of such an operation involves the manipulation of data. If such acts are implemented exclusively or near-exclusively in hardware, such as within a FPGA or an ASIC, the computer-executable instructions may be hard-coded or hard-wired logic gates. The computer-executable instructions (and the manipulated data) may be stored in the memory 904 of the computing system 900. Computing system 900 may also contain communication channels 908 that allow the computing system 900 to communicate with other computing systems over, for example, network 910.

While not all computing systems require a user interface, in some embodiments, the computing system 900 includes a user interface system 912 for use in interfacing with a user. The user interface system 912 may include output mechanisms 912A as well as input mechanisms 912B. The principles described herein are not limited to the precise output mechanisms 912A or input mechanisms 912B as such will depend on the nature of the device. However, output mechanisms 912A might include, for instance, speakers, displays, tactile output, virtual or augmented reality, holograms and so forth. Examples of input mechanisms 912B might include, for instance, microphones, touchscreens, virtual or augmented reality, holograms, cameras, keyboards, mouse or other pointer input, sensors of any type, and so forth.

Embodiments described herein may comprise or utilize a special-purpose or general-purpose computing system including computer hardware, such as, for example, one or more processors and system memory, as discussed in greater detail below. Embodiments described herein also include physical and other computer-readable media for carrying or storing computer-executable instructions and/or data structures. Such computer-readable media can be any available media that can be accessed by a general-purpose or special-purpose computing system. Computer-readable media that store computer-executable instructions are physical storage media. Computer-readable media that carry computer-executable instructions are transmission media. Thus, by way of example, and not limitation, embodiments of the invention can comprise at least two distinctly different kinds of computer-readable media: storage media and transmission media.

Computer-readable storage media includes RAM, ROM, EEPROM, CD-ROM, or other optical disk storage, magnetic disk storage, or other magnetic storage devices, or any other physical and tangible storage medium which can be used to store desired program code means in the form of computer-executable instructions or data structures and which can be accessed by a general-purpose or special-purpose computing system.

A “network” is defined as one or more data links that enable the transport of electronic data between computing systems and/or modules and/or other electronic devices. When information is transferred or provided over a network or another communications connection (either hardwired, wireless, or a combination of hardwired or wireless) to a computing system, the computing system properly views the connection as a transmission medium. Transmission media can include a network and/or data links which can be used to carry desired program code means in the form of computer-executable instructions or data structures and which can be accessed by a general-purpose or special-purpose computing system. Combinations of the above should also be included within the scope of computer-readable media.

Further, upon reaching various computing system components, program code means in the form of computer-executable instructions or data structures can be transferred automatically from transmission media to storage media (or vice versa). For example, computer-executable instructions or data structures received over a network or data link can be buffered in RAM within a network interface module (e.g., a “NIC”), and then be eventually transferred to computing system RAM and/or to less volatile storage media at a computing system. Thus, it should be understood that storage media can be included in computing system components that also (or even primarily) utilize transmission media.

Computer-executable instructions comprise, for example, instructions and data which, when executed at a processor, cause a general-purpose computing system, special-purpose computing system, or special-purpose processing device to perform a certain function or group of functions. Alternatively, or in addition, the computer-executable instructions may configure the computing system to perform a certain function or group of functions. The computer executable instructions may be, for example, binaries or even instructions that undergo some translation (such as compilation) before direct execution by the processors, such as intermediate format instructions such as assembly language, or even source code.

Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the invention may be practiced in network computing environments with many types of computing system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, datacenters, wearables (such as glasses) and the like. The invention may also be practiced in distributed system environments where local and remote computing system, which are linked (either by hardwired data links, wireless data links, or by a combination of hardwired and wireless data links) through a network, both perform tasks. In a distributed system environment, program modules may be located in both local and remote memory storage devices.

Those skilled in the art will also appreciate that the invention may be practiced in a cloud computing environment. Cloud computing environments may be distributed, although this is not required. When distributed, cloud computing environments may be distributed internationally within an organization and/or have components possessed across multiple organizations. In this description and the following claims, “cloud computing” is defined as a model for enabling on-demand network access to a shared pool of configurable computing resources (e.g., networks, servers, storage, applications, and services). The definition of “cloud computing” is not limited to any of the other numerous advantages that can be obtained from such a model when properly deployed.

For the processes and methods disclosed herein, the operations performed in the processes and methods may be implemented in differing order. Furthermore, the outlined operations are only provided as examples, and some of the operations may be optional, combined into fewer steps and operations, supplemented with further operations, or expanded into additional operations without detracting from the essence of the disclosed embodiments.

The present invention may be embodied in other specific forms without departing from its spirit or characteristics. The described embodiments are to be considered in all respects only as illustrative and not restrictive. The scope of the invention is, therefore, indicate by the appended claims rather than by the foregoing description. All changes which come within the meaning and range of equivalency of the claims are to be embraced within their scope.

What is claimed is:

1. A flip chip micromirror assembly comprising:
a circuit board having electrode surface in which at least a first board electrode is formed;
a micromirror chip having a micromirror layer in which a micromirror is formed, and including a flip chip surface facing the electrode surface of the circuit board, the flip chip surface having at least a first chip electrodes formed therein; and
a bonding layer interposed between the electrode surface of the circuit board and the flip chip surface of the micromirror layer, the bonding layer including a first conductive region that electrically couples the first board electrode of the circuit board with the first chip electrode of the micromirror layer, the bonding layer having a thickness sufficient to provide a gap underneath the micromirror between the micromirror chip and the circuit board sufficient to permit full actuation of the micromirror.

2. The flip chip micromirror assembly in accordance with claim 1, a reflective side of the micromirror being on a side opposite the flip chip surface of the micromirror layer and facing away from the circuit board.

3. The flip chip micromirror assembly in accordance with claim 1, the circuit board having a hole formed therein at a position corresponding to the micromirror, a most reflective side of the micromirror being on a side facing towards the circuit board at a position of the hole of the printed circuit board.

4. The flip chip micromirror assembly in accordance with claim 3, the micromirror chip comprising a semiconductor substrate positioned further from the circuit board than the micromirror layer.

5. The flip chip micromirror assembly in accordance with claim 1, a plurality of chip electrodes including the first chip electrode being formed in the flip chip surface of the micromirror layer of the micromirror chip, a plurality of board electrodes including the first board electrode being formed in the electrode surface of the circuit board, the bonding layer including a plurality of conductive regions including the first conductive region, each of the plurality of conductive regions electrically coupling one or more of the plurality of chip electrodes with one or more of the plurality of board electrodes.

6. The flip chip micromirror assembly in accordance with claim 5, the micromirror chip comprising an etch stop layer that defines a surface of the micromirror chip that faces away from the circuit board.

7. The flip chip micromirror assembly in accordance with claim 1, the conductive region of the bonding layer comprising an anisotropic conductive region comprising a plurality of compressed spheres.

8. The flip chip micromirror assembly in accordance with claim 1, the conductive region of the bonding layer comprising bulk bonding material.

9. An optical system comprising:
a flip chip micromirror assembly comprising:
a circuit board having electrode surface in which at least a first board electrode is formed;
a micromirror chip having a micromirror layer in which a micromirror is formed, and including a flip chip surface facing the electrode surface of the circuit board, the flip chip surface having at least a first chip electrodes formed therein; and
a bonding layer interposed between the electrode surface of the circuit board and the flip chip surface of the micromirror layer, the bonding layer including a first conductive region that electrically couples the first board electrode of the circuit board with the first chip electrode of the micromirror layer, the bonding layer having a thickness sufficient to provides a gap underneath the micromirror between the micromirror chip and the circuit board sufficient to permit full actuation of the micromirror; and
an optical source configured to direct an optical signal incident on a reflective surface of the micromirror; and
an actuator configured to actuate the micromirror to reflect the optical signal towards a viewing surface.

10. The optical system in accordance with claim 9, the reflective surface of the micromirror being on a side opposite the flip chip surface of the micromirror layer and facing away from the circuit board.

11. The optical system in accordance with claim 9, the circuit board having a hole formed therein at a position corresponding to the micromirror, the reflective surface of the micromirror being on a side facing towards the circuit board at a position of the hole of the printed circuit board, the optical signal incident on the reflective surface through the hole in the circuit board, and being reflected from the reflective surface again through the hole in the printed circuit board.

12. The optical system in accordance with claim 11, the micromirror chip comprising a semiconductor substrate positioned further from the circuit board than the micromirror layer.

13. The optical system in accordance with claim 9, a plurality of chip electrodes including the first chip electrode being formed in the flip chip surface of the micromirror layer of the micromirror chip, a plurality of board electrodes including the first board electrode being formed in the electrode surface of the circuit board, the bonding layer including a plurality of conductive regions including the first conductive region, each of the plurality of conductive regions electrically coupling one or more of the plurality of chip electrodes with one or more of the plurality of board electrodes.

14. The optical system in accordance with claim 13, the micromirror chip comprising an etch stop layer that defines a surface of the micromirror chip that faces away from the circuit board.

15. The optical system in accordance with claim 9, the conductive region of the bonding layer comprising an anisotropic conductive region comprising a plurality of compressed spheres.

16. The optical system in accordance with claim 9, the conductive region of the bonding layer comprising bulk bonding material.

17. The optical system in accordance with claim 9, the optical system being a wearable device on which the viewing surface is visible to an eye of a user if the wearable device is worn by a user.

18. A method for manufacturing a flip chip micromirror assembly, the method comprising:
fabricating a micromirror chip having a micromirror layer in which a micromirror is formed, and including a flip chip surface having at least a first chip electrodes formed therein;
flipping the fabricated micromirror chip towards an electrode surface of a circuit board, so that the flip chip surface of the micromirror chip faces the electrode surface of the circuit board;
bonding the flip chip surface of the micromirror chip to the electrode surface of the circuit board with a bonding layering interposed between the flip chip surface of the micromirror chip and the electrode surface of the circuit board, so that each of a plurality of conductive regions of the bonding electrically couples one or more of the plurality of chip electrodes with one or more of the plurality of board electrodes; and
hardening the bonding so to provide a bonding layer that structurally supports that micromirror chip on the circuit board while providing a space for the micromirror to be fully actuated.

19. The method in accordance with claim 18, the reflective surface of the micromirror being on a side opposite the flip chip surface of the micromirror layer and facing away from the circuit board.

20. The method in accordance with claim 18, the circuit board having a hole formed therein at a position corresponding to the micromirror, the reflective surface of the micromirror being on a side facing towards the circuit board at a position of the hole of the printed circuit board, the optical signal incident on the reflective surface through the hole in the circuit board, and being reflected from the reflective surface again through the hole in the printed circuit board.
